(19) United States
(12) Patent Application Publication
(10) Pub. No.: US 2014/0174797 A1
(43) Pub. Date: Jun. 26, 2014

(54) BUILD-UP FILM STRUCTURE, CIRCUIT BOARD MANUFACTURED USING THE SAME, AND METHOD FOR MANUFACTURING CIRCUIT BOARD USING THE SAME

(71) Applicant: SAMSUNG ELECTRO-MECHANICS CO., LTD., Suwon (KR)

(72) Inventors: Ji Hye SHIM, Suwon (KR); Hwa Young Lee, Suwon (KR)

(73) Assignee: SAMSUNG ELECTRO-MECHANICS CO., LTD., Suwon (KR)

(21) Appl. No.: 13/827,310

(22) Filed: Mar. 14, 2013

(30) Foreign Application Priority Data
Dec. 20, 2012 (KR) 10-2012-0149573

(51) Int. Cl. H05K 1/03; H01B 13/00

(52) U.S. Cl. CPC H05K 1/0373; H01B 13/00; H05K 1/036
USPC 174/255; 156/52; 428/354; 428/216; 428/414

(57) ABSTRACT

Disclosed herein is a build-up film structure including: a core layer containing a resin and an inorganic filler; a first adhesive layer covering one surface of the core layer and having a smaller content of the inorganic filler than that of the core layer; and a second adhesive layer covering the other surface of the core layer and having a smaller content of the inorganic filler than that of the core layer.

### CROSS REFERENCE(S) TO RELATED APPLICATIONS

This application claims the benefit under 35 U.S.C. Section 119 of Korean Patent Application Serial No. 10-2012-0149573, entitled “Build-up Film Structure, Circuit Board Manufactured Using the Same, and Method For Manufacturing Circuit Board Using the Same” filed on Dec. 20, 2012, which is hereby incorporated by reference in its entirety into this application.

### BACKGROUND OF THE INVENTION

1. Technical Field

The present invention relates to a build-up film structure, and more particularly, a build-up film structure capable of increasing adhesion between one surface thereof and a board and increasing close adhesion between the other surface thereof and a plating pattern, a circuit board manufactured using the same, and a method for manufacturing a circuit board using the same.

2. Description of the Related Art

Currently, a thin circuit board such as a printed circuit board (PCB) is manufactured by sequentially laminating and compressing various kinds of build-up insulating films for thinness and high integration. The build-up film is provided in a significantly thin plate shape, and ordinarily, both surfaces of the build-up insulating film are protected by attaching predetermined protective films thereon. Then, at the time of manufacturing the printed circuit board, the protective film is removed from a build-up board and only the build-up insulating film is selectively used.

In accordance with the recent trend toward thinness of the printed circuit board, in order to minimize warpage such as bending, twisting of a package, or the like, the build-up insulating film should have a low coefficient of thermal expansion (CTE) property. In addition, as a signal transferring speed between the circuits at a high frequency is increased, the build-up insulating film should also have a low dissipation factor (Df) property. In order to satisfy this low CTE property, an inorganic filler such as silica is added to a material of the build-up film, and in order to satisfy the low Df property, an ester based curing agent is added to the material of the build-up film.

However, in the case of increasing a content of the filler such as silica, a brittleness property of the build-up film increases, which decreases handle-ability, and lamination efficiency with respect to the board decreases. Further, in the case of using the ester based curing agent, an etching solution such as potassium permanganate (KMnO₄) that is used in a desmear process for forming a circuit pattern on the build-up film may not completely remove a residue of the build-up film.

### RELATED ART DOCUMENT

[Patent Document]
(Patent Document 1) Japanese Patent Laid-open Publication No. 2010-238990

### SUMMARY OF THE INVENTION

An object of the present invention is to provide a build-up film structure capable of increasing adhesion to a board at one surface and the close adhesion to a plating pattern at the other surface while securing curing properties as an interlayer insulating film.

Another object of the present invention is to provide a build-up film structure capable of improving efficiency of removing a residue of the build-up film at the time of performing a desmear process while maintaining a low coefficient of thermal expansion (CTE) property and a low dissipation factor (Df) property.

Still another object of the present invention is to provide a circuit board having a low CTE property and a low Df property, and a method for manufacturing the same.

Still another object of the present invention is to provide a method for manufacturing a circuit board capable of efficiently removing a film residue during a desmear process at the time of manufacturing a circuit board.

According to an exemplary embodiment of the present invention, there is provided a build-up film structure including: a core layer containing a resin and an inorganic filler; a first adhesive layer covering one surface of the core layer and having a smaller content of the inorganic filler than that of the core layer; and a second adhesive layer covering the other surface of the core layer and having a smaller content of the inorganic filler than that of the core layer.

The inorganic filler may contain at least one of silica, calcium carbonate (CaCO₃), phyllosilicate, talc, and ceramic powder.

The core layer may have an inorganic filler content of 50 wt.% or more, and the first and second adhesive layers may have inorganic filler contents less than 50 wt. %.

The core layer may have a thickness of 10 to 30 μm, the first adhesive layer may have a thickness of 1 to 3 μm, and the second adhesive layer may have a thickness of 1 to 5 μm.

The resin may contain at least one of a bisphenol A type epoxy resin, a cresol novolac epoxy resin, a rubber modified epoxy resin, and a phosphorus based epoxy resin.

The build-up film structure may further include: a carrier film covering the first adhesive layer; and a cover film covering the second adhesive layer.

According to another exemplary embodiment of the present invention, there is provided a circuit board including: a board provided with a circuit pattern; an insulating film adhered to the board; and a plating pattern formed on the insulating film, wherein the insulating film includes a core layer containing a resin and an inorganic filler; a first adhesive layer covering one surface of the core layer and having a smaller content of the inorganic filler than that of the core layer; and a second adhesive layer covering the other surface of the core layer and having a smaller content of the inorganic filler than that of the core layer.

According to another exemplary embodiment of the present invention, there is provided a method for a circuit board including: preparing a build-up film structure including a core layer containing a resin and an inorganic filler; a first adhesive layer covering one surface of the core layer and having a smaller content of the inorganic filler than that of the core layer; and a second adhesive layer covering the other surface of the core layer and having a smaller content of the inorganic filler than that of the core layer; separating a carrier film from the build-up film structure so that the first adhesive layer is exposed; adhering the exposed first adhesive layer to a board for manufacturing a build-up printed circuit board; separating a cover film from the build-up film structure so that the second adhesive layer is exposed; performing a desmear process on the second adhesive layer to allow the second adhesive layer to have a surface roughness; and forming a plating pattern on the second adhesive layer with the roughness.

### BRIEF DESCRIPTION OF THE DRAWINGS

FIG. 1 is a view showing a build-up film structure according to an exemplary embodiment of the present invention;

FIG. 2 is a flow chart showing a method for manufacturing a circuit board according to the exemplary embodiment of the present invention; and

FIGS. 3A to 3E are views for explaining a process for manufacturing a circuit board according to an exemplary embodiment of the present invention.

### DESCRIPTION OF THE PREFERRED EMBODIMENTS

Various advantages and features of the present invention and methods accomplishing thereof will become apparent from the following description of embodiments with reference to the accompanying drawings. However, the present invention may be modified in many different forms and it should not be limited to the embodiments set forth herein. Rather, these embodiments may be provided so that this disclosure will be thorough and complete, and will fully convey the scope of the invention to those skilled in the art. Like reference numerals throughout the specification denote like elements.

Terms used in the present specification are for explaining the embodiments rather than limiting the present invention. Unless explicitly described to the contrary, a singular form includes a plural form in the present specification. The word “comprise” and variations such as “comprises” or “comprising,” will be understood to imply the inclusion of stated constituents, steps, operations and/or elements but not the exclusion of any other constituents, steps, operations and/or elements.

Further, the exemplary embodiments described in the specification will be described with reference to cross-sectional views and/or plan views that are ideal exemplification figures. In the drawings, the thickness of layers and regions is exaggerated for efficient description of the technical contents. Therefore, exemplified forms may be changed according to manufacturing technologies and/or tolerance. Therefore, the exemplary embodiments of the present invention are not limited to specific forms but may include the change in forms generated according to the manufacturing processes For example, an etching region vertically shown may be rounded or may have a predetermined curvature.

Hereinafter, a build-up film structure, a circuit board manufactured using a build-up film structure, and a method for manufacturing a circuit board using a build-up film structure according to the exemplary embodiment of the present invention will be described in detail with reference to the accompanying drawings.

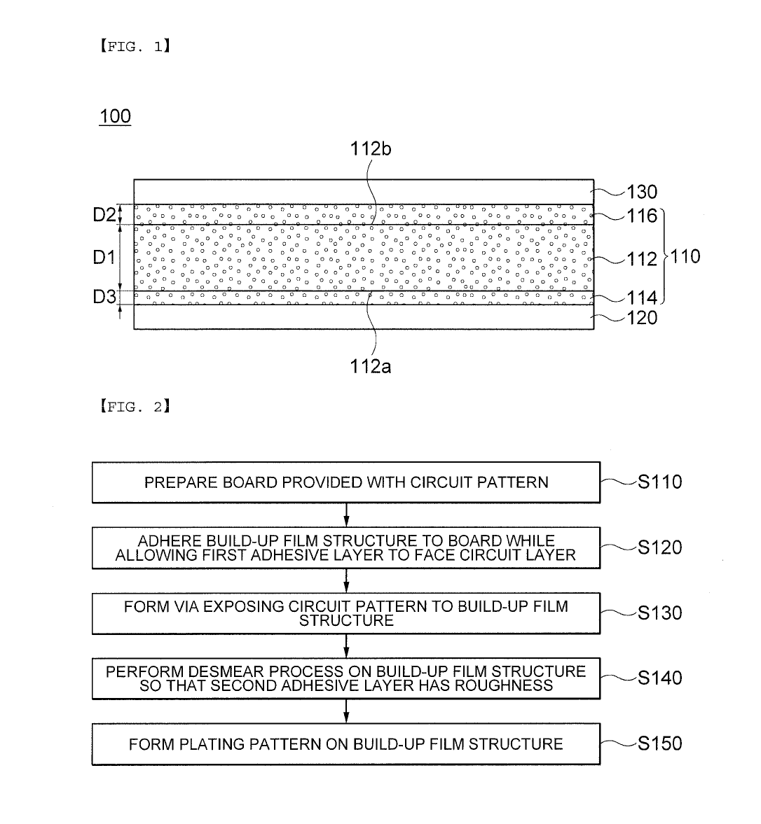

FIG. 1 is a view showing a build-up film structure according to an exemplary embodiment of the present invention. Referring to FIG. 1, the build-up film structure 100 according to the exemplary embodiment of the present invention may include an insulating film 110, a carrier film 120, and a cover film 130.

The insulating film 110 is to manufacture a predetermined circuit board, and the carrier film 120 and the cover film 130 are to move and protect the insulating film 110. Therefore, during a process of manufacturing the circuit board using the build-up film structure 110, the carrier film 120 and the cover film 130 may be separated and removed from the build-up film structure 100, and only the insulating film 110 may be selectively used.

The insulating film 110 may be to manufacture a interlayer insulating layer configuring a flexible printed circuit board (PCB), a rigid PCB, a RF PCB, a build-up PCB, other various kinds of package boards, or the like. In this case, the insulating layer may be formed by laminating, compressing and sintering a plurality of insulating layers 110, and the insulating film 110 may be formed as one film for configuring one layer of the build-up PCB.

The insulating film 110 may include a core layer 112, a first adhesive layer 114 adhered to one surface 112a of the core layer 112, and a second adhesive layer 116 adhered to the other surface 112b of the core layer 112. The first and second adhesive layers 114 and 116 may be made of a composite material made of an insulating material, an inorganic filler, and other additives, respectively.

The insulating material may be made of an epoxy resin and other various additives. The epoxy resin may include at least one of a bisphenol A type epoxy resin, a cresol novolac epoxy resin, a rubber modified epoxy resin, and a phosphorus based epoxy resin. For example, as the epoxy resin, a composite epoxy resin composition made of the bisphenol A type epoxy resin, the cresol novolac epoxy resin, the rubber modified epoxy resin, and the phosphorus based epoxy resin may be used.

The bisphenol A type epoxy resin may be adjusted to have an average epoxy resin equivalent of 100 to 700. In the case in which the average epoxy resin equivalent is less than 100, it may be difficult to obtain physical properties required in the insulating material. On the contrary, in the case in which the average epoxy resin equivalent is more than 700, since it is difficult to dissolve the epoxy resin in a solvent, and a melting point excessively increases, it may not be easy to manufacture the insulating film 110. In addition, a content of the bisphenol A type epoxy resin may be adjusted to 1 to 20 parts by weight based on 100 parts by weight of the composite epoxy resin composition. In the case in which the content of the bisphenol A type epoxy resin is less than 1 part by weight, adhesion to a circuit wiring formed on the insulating layer may be decreased. On the contrary, when the content of the bisphenol A type epoxy resin is more than 20 parts by weight, thermal and electrical properties and moisture resistance of the insulating material may be decreased.

The cresol novolac epoxy resin has a feature that a cured product having high heat resistance may be obtained, thereby making it possible to improve thermal stability of a circuit board to be manufactured. The cresol novolac epoxy resin may be adjusted to have an average epoxy resin equivalent of 100 to 600. In the case in which the average epoxy resin equivalent of the cresol novolac epoxy resin is less than 100, it may be difficult to obtain the physical property required in the insulating material. On the contrary, in the case in which the average epoxy resin equivalent of the cresol novolac epoxy resin is more than 600, since it is difficult to dissolve the epoxy resin in a solvent, and a melting point excessively increases, it may not be easy to manufacture the insulating film 110. In addition, a content of the cresol novolac epoxy resin may be adjusted to 30 to 70 parts by weight based on 100 parts by weight of the composite epoxy resin composition. In the case in which the content of the cresol novolac epoxy resin in the composite epoxy resin composition is less than 30 parts by weight, the thermal and mechanical properties required in the insulating film 110 may not be obtained, and in the case in which the content is more than 70 parts by weight, a final cured product may be easily brittle, and impact resistance may be decreased.

The rubber modified epoxy resin may be adjusted to have an average epoxy resin equivalent of 100 to 500. In the case in which the average epoxy resin equivalent of the rubber modified epoxy resin is less than 100, it may be difficult to obtain the physical property required in the insulating material, and in the case in which the average epoxy resin equivalent is more than 500, since it is difficult to dissolve the epoxy resin in a solvent, and a melting point excessively increases, it may not be easy to manufacture the insulating film 110. In addition, a content of the rubber modified epoxy resin may be adjusted to 1 to 20 parts by weight based on 100 parts by weight of the composite epoxy resin composition. In the case in which the content of the rubber modified epoxy resin is less than 1 part by weight, the physical properties required in the insulating film 110 may not be obtained, and in the case in which the content is more than 20 parts by weight, a final cured product may become easily brittle, such that crack generation may be increased and impact resistance may be decreased.

The phosphorus based epoxy resin may have excellent flame retardant property and self-extinguishing property. Therefore, the phosphorus based epoxy resin may be added in order to impart the flame retardant property to the printed circuit board. The phosphorus based epoxy resin may be adjusted to have an average epoxy resin equivalent of 400 to 800. In the case in which the average epoxy resin equivalent of the phosphorus based epoxy resin is less than 400, it may be difficult to obtain the physical property required in the insulating material, and in the case in which the average epoxy resin equivalent is more than 800, since it is difficult to dissolve the epoxy resin in a solvent, and a melting point excessively increases, it may not be easy to manufacture the insulating film 110. In addition, a content of the phosphorus based epoxy resin may be adjusted to 1 to 30 parts by weight based on 100 parts by weight of the composite epoxy resin composition. In the case in which the content of the phosphorus based epoxy resin is less than 1 part by weight, it may be difficult to obtain the flame retardant property required in the insulating film 110, and in the case in which the content is more than 30 parts by weight, the electrical and mechanical properties of the insulating film 110 may be deteriorated.

The inorganic filler may be provided in order to improve the mechanical, electrical, and thermal properties of the insulating film 110. For example, as the inorganic filler, at least one of silica, phyllosilicate, talc, and ceramic powder may be used. As an example, as the inorganic filler, amorphous silica may be used. Generally, the silica has a spherical shape and may be added so as to be approximately uniformly distributed in the entire insulating material. As the silica, amorphous silica surface-treated with curable silane may be used. As another example of the inorganic filler, metal oxide powder containing at least one of aluminum, magnesium, zinc, calcium, strontium, zirconium, barium, neodymium, bismuth, lithium, samarium, and tantalum may be used.

The additives may include a curing agent, a curing accelerator, a flame retardant adjuvant, and the like.

As the curing agent, a phenol based curing agent or ester based curing agent may be used. The curing agent may be mixed at an equivalent ratio of 0.5 to 1.3 based on the combined epoxy equivalent of the composite epoxy resin composition. When the curing agent is mixed in the above-mentioned range of the equivalent ratio, a degree of curing of the circuit board to be manufactured may be easily adjusted during a process of manufacturing the board, and coefficient of the thermal expansion of the circuit board may be decreased. In the case in which the equivalent ratio of the curing agent is less than 0.5, the thermal and mechanical properties of the composite resin composition may be deteriorated, and in the case in which the equivalent ratio is more than 1.3, adhesion may be deteriorated, and un-reacted curing agent may be generated.

Here, the core layer 112 contains the phenol base curing agent or the ester based curing agent, but the first and second adhesive layers 114 and 116 may selectively not contain the curing agent. Particularly, in the second adhesive layer 116, the ester based curing agent among the curing agents may not be contained, or be minimally contained. The reason is that a desmear process for forming a plating pattern may be performed later on the second adhesive layer 116, but in the case in which the second adhesive layer contains the ester based curing agent as described above, a film residue may not be completely removed during the desmear process. Therefore, the curing agent is not contained in at least one of the first and second adhesive layers 114 and 116, more specifically, the second adhesive layer 116, such that removal efficiency of the film residue at the time of performing the desmear process may be improved.

As the curing accelerator, an imidazole based curing accelerator may be used. For example, as the curing accelerator, at least one of 2-ethyl-4-methyl imidazole, 1-(2-cyanoethyl)-2-alkyl imidazole, and 2-phenyl imidazole may be used. The curing accelerator may be adjusted to have a content of 0.1 to 2 parts by weight in the composite resin composition. In the case in which the content of the curing accelerator is less than 0.1 parts by weight, a curing rate may be significantly decreased, such that the composite resin composition may not be cured. On the contrary, in the case in which the content of the curing accelerator is more than 2 parts by weight, it may be difficult to control the curing rate, such that it may be difficult to secure reproducibility in a manufacturing process step.

The flame retardant adjuvant is used in order to decrease the content of a flame retardant epoxy resin that is relatively expensive. As the flame retardant, a compound such as Al₂O₃ containing phosphorus may be used.

Meanwhile, compositions of each of the core layer 112 and the first and second adhesive layers 114 and 116 may be variously adjusted so as to be appropriate for each of the functions.

The core layer 112 may be formed so as to have a low CTE property and low Df property. To this end, in a composite material for manufacturing the core layer 112, the content of the organic filler may be relatively higher than that of the first and second adhesive layers 114 and 116, and the ester based curing agent may be contained. As an example, a content of silica in the core layer 112 may be 50 wt. % or more based on the entire resin-inorganic composite material composition for manufacturing the core layer 112. Further, although the content of the silica in the core layer 112 is high, which deteriorates handle-ability and a lamination property, since the first and second adhesive layers 114 and 116 may complement the low handle-ability and lamination property of the core layer 112, the content of the silica in the core layer 112 may be 70 wt. % or more. In the case in which the content of silica is less than 50 wt. %, it may be difficult to implement the above-mentioned low CTE property and low Df property.

The first adhesive layer 114 may be a portion adhered to a board of the circuit board at the time of manufacturing the circuit board. Therefore, the first adhesive layer 114 may be formed so as to have strong adhesion to the board together with being strongly adhered to the core layer 112. In the case in which the content of the silica is high, flow-ability may be decreased, such that the lamination efficiency with respect to the board may be decreased. Therefore, in order to increase the lamination efficiency of the build-up film structure 100 with respect to the board, the content of the inorganic filler, that is, silica in the first adhesive layer 114 may be lower than that of the core layer 112. As an example, a content of silica in the first adhesive layer 114 may be less than 50 wt. % based on the entire resin-inorganic composite material composition for manufacturing the first adhesive layer 114. In the case in which the content of silica in the first adhesive layer 114 is more than 50 wt. %, flow-ability of the first adhesive layer 114 is decreased, such that lamination efficiency with respect to the board may be decreased. Further, the content of silica may be about 15 wt. % or more based on the entire resin-inorganic composite material. When the content of silica is less than 15 wt. %, the CTE property of the first adhesive layer 114 is significantly decreased, such that functions of the first adhesive layer 114 may be deteriorated.

In addition, the second adhesive layer 116 may be formed so as to have high close adhesion to the plating pattern formed on the second adhesive layer 116 together with being strongly adhered to the core layer 112. In the case in which the content of silica in the second adhesive layer 116 is high or an active ester curing agent is used, a desmear property with respect to the second adhesive layer 116 may be deteriorated. Therefore, in order to improve the desmear property, in the second adhesive layer 116, the content of the inorganic filler, that is, silica may be lower than that of the core layer 112. In addition, the phenol based curing agent may be used at a minimal content or not be used so that large roughness is not formed during the desmear process. As an example, the content of silica in the second adhesive layer 116 may be less than 50 wt. % based on the entire resin-inorganic composite material composition for manufacturing the second adhesive layer 116, and the ester based curing agent may be used. In the case in which the content of silica in the second adhesive layer 116 is more than 50 wt. %, efficiency of the desmear process with respect to the second adhesive layer 116 is decreased, such that close adhesion to the plating pattern formed thereon may be deteriorated. Further, the content of silica may be about 15 wt. % or more based on the entire resin-inorganic composite material. When the content of silica is less than 15 wt. %, the CTE property of the second adhesive layer 116 is significantly decreased, such that functions of the second adhesive layer 116 may be deteriorated.

In addition, a thickness of each of the core layer 112 and the first and second adhesive layers 114 and 116 may be variously adjusted so as to be appropriate for each of the functions.

The core layer 112, which is to form a main portion of an interlayer insulating film of the circuit board, may have a thickness thicker than those of the first and second adhesive layers 114 and 116. On the other hand, the first adhesive layer 114, which is to increase the adhesion to the board, may have a minimum thickness as long as the function of increasing the adhesion may be implemented. Particularly, since the first adhesive layer 114 may fill spaces between the circuit patterns formed on the board, the first adhesive layer 114 may have a thickness similar to or slightly thicker than that of the circuit pattern. In addition, the second adhesive layer 116, which is to increase the efficiency of the desmear process for increasing close adhesion to the plating pattern formed thereon, may have a minimum thickness as long as the function of increasing the close adhesion may be implemented.

Considering the above-mentioned conditions, the thickness of the core layer 112 may be approximately 10 to 30 μm. The thickness of the core layer 112 may be to secure a function as the interlayer insulating film of the build-up circuit board. When the thickness of the core layer 112 is less than 10 μm, it may be difficult to implement a function that the core layer 112 may minimize a signal loss as the interlayer insulating film. On the other hand, when the thickness of the core layer 112 is more than 30 μm, it may be difficult to satisfy the trend toward thinness of the circuit board.

The thickness of the first adhesive layer 114 may become thin as a ratio of residual copper foil of the board adhered to the first adhesive layer 114 is increased. The thickness of the first adhesive layer 114 may be adjusted to about 1 to 3 μm. In the case in which the thickness of the first adhesive layer 114 is less than 1 μm, when the first adhesive layer 114 is adhered to a circuit board 200 on which circuit patterns are formed, the first adhesive layer 114 may not fill a space between the circuit patterns. On the other hand, in the case in which the thickness of the first adhesive layer 114 is more than 3 μm, the CTE of the first adhesive layer 114 is increased and the flowability thereof is decreased, such that the lamination property of the first adhesive layer 114 may be deteriorated, and it may be difficult to achieve the object of separately providing the first adhesive layer 114 other than the core layer 112.

The thickness of the second adhesive layer 116 may be more than a roughness value Rz formed after the desmear process and less than a value obtained by adding 1 μm to the roughness value Rz. Considering this fact, the thickness of the second adhesive layer 116 may be adjusted to about 1 to 5 μm. In the case in which the thickness of the second adhesive layer 116 is less than 1 μm, since the minimum thickness for allowing the second adhesive layer 116 to have a surface roughness is not secured, the core layer 112 may be exposed while performing the desmear process on the second adhesive layer 116. On the other hand, in the case in which the thickness of the second adhesive layer 116 is more than 5 μm, the CTE of the second adhesive layer 116 is increased, consequently, it may be difficult to achieve the object of separately providing the second adhesive layer 116 other than the core layer 112.

As described above, the build-up film structure 100 according to the exemplary embodiment of the present invention may include the core layer 112 that will become the interlayer insulating film at the time of manufacturing the circuit board, the first adhesive layer 114 covering one surface 112a of the core layer 112 to be adhered to the board, and the second adhesive layer 116 covering the other surface 112b of the core layer 112 and including the plating pattern formed thereon, wherein the core layer 112 may have a relatively high inorganic filler content so as to have low CTE property and low Df property, the first adhesive layer 114 may have a relatively low inorganic filler content so as to have high adhesion to the board, and the second adhesive 116 may have a relatively low inorganic filler content so as to have high close adhesion to the plating pattern. In this case, the build-up film structure 100 may have a structure in which curing properties such as the CTE and the Df of the core layer 112 that will become the interlayer insulating film are improved, and properties of the other outer layers are improved so as to correspond to their functions, respectively. Therefore, the build-up film structure according to the exemplary embodiment of the present invention may have a structure in which the adhesion to the board at one surface thereof and the close adhesion to the plating pattern may be increased while securing the curing property as the interlayer insulating film. Further, in the case of using this build-up film structure to manufacture a circuit board, a highly reliable circuit board capable of increasing adhesion reliability to the circuit pattern and having high warpage property may be manufactured.

Next, a process of manufacturing a circuit board using the above-mentioned build-up film structure 100 will be described in detail. Herein, a description overlapped with the build-up film structure 100 as described above may be omitted or simplified.

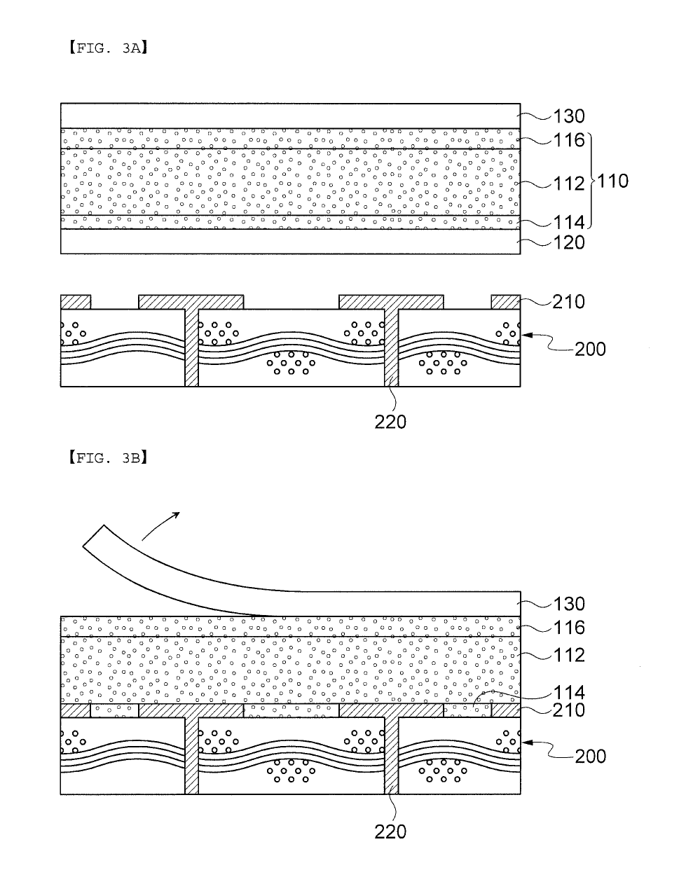

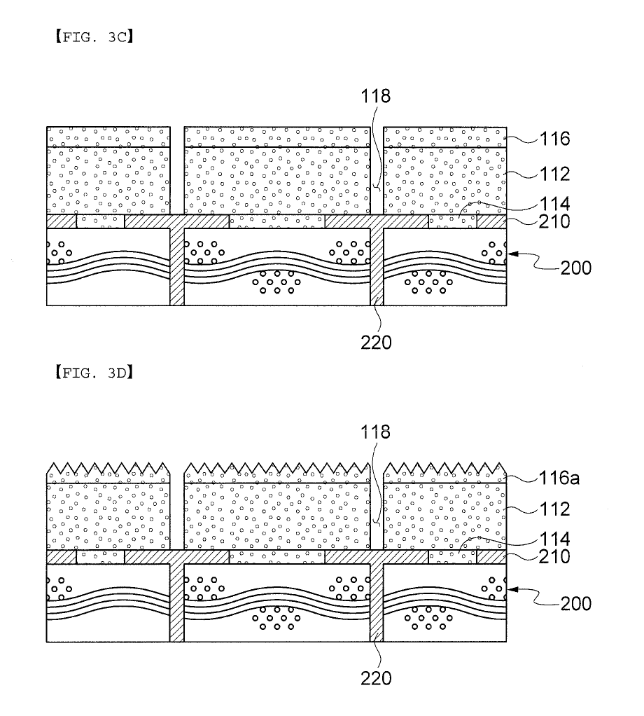

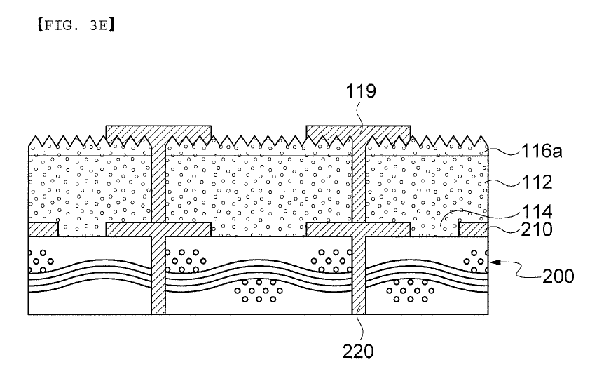

FIG. 2 is a flow chart showing a method for manufacturing a circuit board according to the exemplary embodiment of the present invention; and FIGS. 3A to 3E are views describing a process of manufacturing the circuit board according to the exemplary embodiment of the present invention.

Referring to FIGS. 2 and 3A, a board 200 including a circuit pattern 210 formed thereon may be prepared (S110). As an example, preparing of the board 200 may be performed by preparing a copper clad laminated (CCL), forming via holes in the CCL, and performing a plating process on the CCL to thereby form vias 220 filling the via holes and the circuit pattern 210 electrically connected to the vias 220 on a surface of the CCL.

Referring to FIGS. 2 and 3B, a build-up structure 100 may be adhered to the board 200 in a state in which a first adhesive layer 114 faces the board 220 (S120). For example, the build-up film structure 100 described with reference to FIG. 1 is prepared, and then the build-up film structure 100 may be moved at a place at which a printed circuit board is manufactured. In this case, during a process of moving the build-up film structure to the process place, the carrier film 120 and protective film 130 may protect the build-up film structure 100 and prevent the structure 100 from being slid from a moving apparatus for moving the structure 100.

In addition, after the carrier film 120 is separated from the build-up film structure 100 so that the first adhesive layer 114 is exposed, the first adhesive layer 114 may be adhered to the board 200. Then, the cover film 130 may be separated from the insulating film 110 so that the second adhesive layer 116 is exposed. Therefore, the insulating film 110 having a structure in which the first adhesive layer 112, the core layer 112, and the second adhesive layer are sequentially laminated may be formed on the board 200.

Referring to FIGS. 2 and 3C, the via holes 118 exposing the circuit pattern 210 to the build-up film structure 100 may be formed (S130). In the forming of the via holes 118, through holes exposing the circuit pattern 210 may be formed by performing a laser processing process on regions of the insulating film 110 facing the circuit pattern 210.

Referring to FIGS. 2 and 3D, a desmear process may be performed on the build-up film structure so that the second adhesive layer 116 has a roughness (S140). The desmear process may be performed by etching the second adhesive layer 116 with a predetermined etching solution. As the etching solution, potassium permanganate (KMnO₄) may be used. Potassium permanganate may attach secondary hydroxyl groups generated during the epoxy curing reaction of the insulating film 110 to break the bond roughen the insulating film 110, thereby roughening the insulating film 110. Therefore, a second adhesive layer 116a having surface roughness may be formed.

Here, since the second adhesive layer 116 does not contain an ester based curing agent, or contain the ester based curing agent at a minimum content, it may be prevented that efficiency of removing a residue of the build-up insulating film is decreased due to activation of the secondary hydroxyl group. Therefore, during the desmear process, the residue of the insulating film 110 remaining in the via hole 118 may be effectively removed.

Referring to FIGS. 2 and 3E, a plating pattern 119 may be formed on the build-up film structure 100 (S150). The forming of the plating pattern 119 may be performed by electroless plating the insulating film 110 to form a via filling the via hole 118 and a plating film covering a surface of the second adhesive layer 116a, and then patterning the plating film. Therefore, the circuit board provided with the first adhesive layer 114 adhered to the board 220 while filling the circuit pattern 210, the core layer 112, which is the interlayer insulating film, and the second adhesive layer 116a covering the core layer 112 and including the plating pattern 119 formed on the surface thereof may be manufactured.

As described above, with the method for manufacturing a circuit board according to the present invention, a circuit board capable of securing high adhesion to the board 200 and close adhesion to the plating pattern 119 while maintaining a warpage property with respect to the core layer 112 that will become the interlayer insulating film using the build-up film structure 110 having a multilayer structure in which each layer has improved functions may be manufactured. Therefore, in the method for manufacturing a circuit board according to the present invention, the build-up film structure securing the curing property as the interlayer insulating film and having a structure in which the adhesion to the board may be improved on one surface and the close adhesion to the plating pattern on the other surface may be improved is used, such that the circuit board capable of increasing reliability for adhesion to the circuit pattern and having high warpage property may be manufactured.

The build-up film structure according to the exemplary embodiment of the present invention may have a structure in which the adhesion to the board on one surface thereof and the close adhesion to the plating pattern on the other surface may be increased while securing the curing property as the interlayer insulating film. Therefore, in the case of using this build-up film structure to manufacture a circuit board, a highly reliable circuit board capable of increasing adhesion reliability to the circuit pattern and having high warpage property may be manufactured.

With the method for manufacturing a circuit board according to the present invention, the build-up film structure securing the curing property as the interlayer insulating film and having a structure in which the adhesion to the board may be improved on one surface and the close adhesion to the plating pattern on the other surface may be improved is used, such that the circuit board capable of increasing reliability for adhesion to the circuit pattern and having high warpage property may be manufactured.

The present invention has been described in connection with what is presently considered to be practical exemplary embodiments. Although the exemplary embodiments of the present invention have been described, the present invention may be changed or modified within the range of concept of the invention disclosed in the specification, the range equivalent to the disclosure and/or the range of the technology or knowledge in the field to which the present invention pertains. The exemplary embodiments described above have been provided to explain the best state in carrying out the present invention. Therefore, they may be carried out in other states known to the field to which the present invention pertains in using other inventions such as the present invention and also be modified in various forms required in specific application fields and usages of the invention. Therefore, it is to be understood that the invention is not limited to the disclosed embodiments. It is to be understood that other embodiments are also included within the spirit and scope of the appended claims.

What is claimed is:

1. A build-up film structure comprising:
a core layer containing a resin and an inorganic filler;
a first adhesive layer covering one surface of the core layer and having a smaller content of the inorganic filler than that of the core layer; and
a second adhesive layer covering the other surface of the core layer and having a smaller content of the inorganic filler than that of the core layer.

2. The build-up film structure according to claim 1, wherein the inorganic filler contains at least one of silica, calcium carbonate (CaCO₃), phyllosilicate, talc, and ceramic powder.

3. The build-up film structure according to claim 1, wherein the core layer has an inorganic filler content of 50 wt.% or more, and the first and second adhesive layers have inorganic filler contents less than 50 wt.%.

4. The build-up film structure according to claim 1, wherein the core layer has a thickness of 10 to 30 μm, the first adhesive layer has a thickness of 1 to 3 μm, and the second adhesive layer has a thickness of 1 to 5 μm.

5. The build-up film structure according to claim 1, wherein the resin contains at least one of a bisphenol A type epoxy resin, a cresol novolac epoxy resin, a rubber modified epoxy resin, and a phosphorus based epoxy resin.

6. The build-up film structure according to claim 1, further comprising:
a carrier film covering the first adhesive layer; and
a cover film covering the second adhesive layer.

7. A circuit board comprising:
a board provided with a circuit pattern;
an insulating film adhered to the board; and
a plating pattern formed on the insulating film,
wherein the insulating film includes a core layer containing a resin and an inorganic filler; a first adhesive layer covering one surface of the core layer and having a smaller content of the inorganic filler than that of the core layer; and a second adhesive layer covering the other surface of the core layer and having a smaller content of the inorganic filler than that of the core layer.

8. A method for a circuit board comprising:
preparing a build-up film structure including a core layer containing a resin and an inorganic filler; a first adhesive layer covering one surface of the core layer and having a smaller content of the inorganic filler than that of the core layer; and a second adhesive layer covering the other surface of the core layer and having a smaller content of the inorganic filler than that of the core layer;
separating a carrier film from the build-up film structure so that the first adhesive layer is exposed;
adhering the exposed first adhesive layer to a board for manufacturing a build-up printed circuit board;
separating a cover film from the build-up film structure so that the second adhesive layer is exposed;
performing a desmear process on the second adhesive layer to allow the second adhesive layer to have a surface roughness; and
forming a plating pattern on the second adhesive layer with the roughness.
